(19) United States
(12) Patent Application Publication
(10) Pub. No.: US 2023/0215740 A1
(43) Pub. Date: Jul. 6, 2023

(54) SUBSTRATE TREATING APPARATUS AND SUBSTRATE TREATING METHOD

(71) Applicant: SEMES CO., LTD., Chungcheongnam-do (KR)

(72) Inventors: Won Young KANG, Gyeonggi-do (KR); Tae Keun KIM, Gyeonggi-do (KR); Kang Sul KIM, Gyeonggi-do (KR); Kyeong Min LEE, Gyeonggi-do (KR); Min Hee CHO, Gyeonggi-do (KR)

(21) Appl. No.: 17/843,919

(22) Filed: Jun. 17, 2022

(30) Foreign Application Priority Data
Dec. 30, 2021 (KR) 10-2021-0192316

(51) Int. Cl. H01L 21/67; B08B 3/10; H01L 21/687; H01L 21/02

(52) U.S. Cl. CPC H01L 21/67051; B08B 3/10; H01L 21/68764; H01L 21/02057

(57) ABSTRACT

There are provided a substrate treating apparatus and a substrate treating method. The substrate treating apparatus includes: a stage on which a substrate is seated, in a chamber; and a treatment liquid supply apparatus supplying a treatment liquid containing a solvent and a solute onto the substrate, wherein the treatment liquid supply apparatus supplies the treatment liquid onto the substrate while moving from a center of the substrate to an outer peripheral surface of the substrate.

### CROSS-REFERENCE TO RELATED APPLICATION

This application claims priority from Korean Patent Application No. 10-2021-0192316 filed on Dec. 30, 2021 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a substrate treating apparatus and a substrate treating method.

### 2. Description of the Related Art

When a semiconductor device or a display device is manufactured, various processes such as photographing, etching, ashing, ion implantation, and thin film deposition are performed. Various treatment liquids are used in each process, and contaminants and particles may be generated during each process. In order to solve such a problem, a cleaning process for cleaning contaminants and particles is performed before and after each process.

### SUMMARY

Aspects of the present disclosure provide a substrate treating apparatus of more uniformly drying a treatment liquid formed on a surface of a substrate in a cleaning process.

Aspects of the present disclosure also provide a substrate treating method of more uniformly drying a treatment liquid formed on a surface of a substrate in a cleaning process.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a block diagram for describing a semiconductor process system according to some exemplary embodiments;

FIG. 2 is a flowchart for describing operations of a substrate treating apparatus according to some exemplary embodiments;

FIGS. 3 and 4 are views for describing a substrate treating apparatus according to some exemplary embodiments;

FIGS. 5 and 6 are views for describing a substrate treating apparatus according to some exemplary embodiments;

FIGS. 7 and 8 are views for describing a substrate treating apparatus according to some exemplary embodiments; and

FIGS. 9 to 11 are views for describing a substrate treating apparatus according to some exemplary embodiments.

### DETAILED DESCRIPTION OF THE EMBODIMENTS

Hereinafter, exemplary embodiments of the present disclosure will be described in detail with reference to the accompanying drawings. Advantages and features of the present disclosure and a method of achieving these advantages and features will become apparent with reference to exemplary embodiments to be described later in detail in conjunction with the accompanying drawings. However, the present disclosure is not limited to exemplary embodiments to be disclosed below, but may be implemented in various different forms, these exemplary embodiments will be provided only in order to make the present disclosure complete and allow one of ordinary skill in the art to completely recognize the scope of the present disclosure, and the present disclosure will be defined by the scope of the claims. Throughout the specification, the same components will be denoted by the same reference numerals.

A phrase “one element or layer ‘on’ another element or layer” includes both of a case where one element or layer is directly on another element or layer and a case where one element or layer is on another element or layer with the other layer or element interposed therebetween. On the other hand, a phrase “one element or layer ‘directly on’ another element or layer” indicates that the other element or layer is not interposed between one element or layer and another element or layer.

The spatially relative terms ‘below’, ‘beneath’, ‘lower’, ‘above’, ‘upper’, and the like, may be used in order to easily describe correlations between one element or component and other elements or components as illustrated in the drawings. The spatially relative terms are to be understood as terms including different directions of elements at the time of being used or at the time of operating in addition to directions illustrated in the drawings. For example, when elements illustrated in the drawings are overturned, an element described as ‘below or beneath’ another element may be put ‘above’ another element. Accordingly, an illustrative term “below” may include both of directions of above and below. Elements may be oriented in other directions as well, and accordingly, spatially relative terms may be interpreted according to orientations.

The terms ‘first’, ‘second’, and the like are used to describe various elements, components, and/or sections, but these elements, components, and/or sections are not limited by these terms. These terms are used only in order to distinguish one element, component, or section from another element, component or section. Accordingly, a first element, a first component, or a first section to be mentioned below may also be a second element, a second component, or a second section within the technical spirit of the present disclosure.

The terms used herein are for describing exemplary embodiments rather than limiting the present disclosure. In the present specification, a singular form includes a plural form unless stated otherwise in the phrase. Components, steps, operations, and/or elements mentioned by the terms “comprise” and/or “comprising” used herein do not exclude the existence or addition of one or more other components, steps, operations, and/or elements.

Unless defined otherwise, all the terms (including technical and scientific terms) used herein have the same meaning as meanings commonly understood by one of ordinary skill in the art to which the present disclosure pertains. In addition, the terms defined in generally used dictionaries are not ideally or excessively interpreted unless they are specifically defined clearly.

Hereinafter, exemplary embodiments of the present disclosure will be described in detail with reference to the accompanying drawings. In describing exemplary embodiments of the present disclosure with reference to the accompanying drawings, components that are the same as or correspond to each other will be denoted by the same reference numerals, and an overlapping description thereof will be omitted.

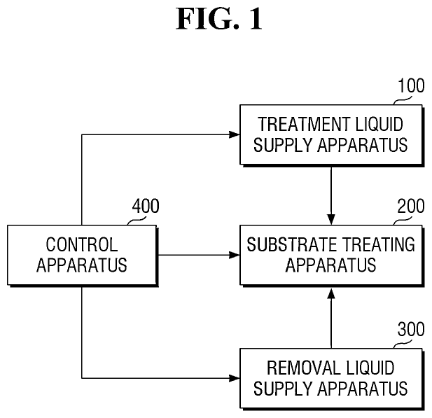

FIG. 1 is a block diagram for describing a semiconductor process system according to some exemplary embodiments.

Referring to FIG. 1, a semiconductor process system may include a treatment liquid supply apparatus 100, a substrate treating apparatus 200, a removal liquid supply apparatus 300, and a control apparatus 400.

The substrate treating apparatus 200 may treat a substrate using a chemical. Such a substrate treating apparatus 200 may be provided in a cleaning process chamber cleaning the substrate using the chemical.

The chemical may be a liquid material (e.g., an organic solvent) or a gaseous material. The chemical may include materials having high volatility and generating a large amount of fumes or having residual properties due to high viscosity. The chemical may be selected from, for example, a material including an isopropyl alcohol (IPA) component, a material including a sulfuric acid component (e.g., a sulfuric peroxide mixture (SPM) including a sulfuric acid component and a hydrogen peroxide component), a material including an ammonia water component (e.g., SC-1(H₂O₂+NH₄OH) and a material including a hydrofluoric acid component (e.g., diluted hydrogen fluoride (DHF)), a material containing a phosphoric acid component, and the like. Hereinafter, these chemicals used to process the substrate will be defined as treatment liquids.

The treatment liquid supply apparatus 100 is an apparatus that provides a treatment liquid to the substrate treating apparatus 200. The treatment liquid supply apparatus 100 may be connected to a jetting module of the substrate treating apparatus 200.

The removal liquid supply apparatus 300 may provide a removal liquid to the substrate treating apparatus 200. The removal liquid supply apparatus 300 may be connected to the jetting module of the substrate treating apparatus 200.

The control apparatus 400 may control the treatment liquid supply apparatus 100, the substrate treating apparatus 200, and the removal liquid supply apparatus 300. The treatment liquid supply apparatus 100 may provide the treatment liquid to the substrate treating apparatus 200 and the removal liquid supply apparatus 300 may provide the removal liquid to the substrate treating apparatus 200, by the control of the control apparatus 400.

The control apparatus 400 may be provided as a computer, a server, or the like, including a process controller, a control program, an input module, an output module (or a display module), a memory module, and the like. Here, the process controller may include a microprocessor executing a control function for respective components constituting the substrate treating apparatus 200, and the control program may execute various treatments of the substrate treating apparatus 200 according to the control of the process controller. The memory module may store a program for executing various treatments of the substrate treating apparatus 200 according to various data and treating conditions, that is, a treating recipe.

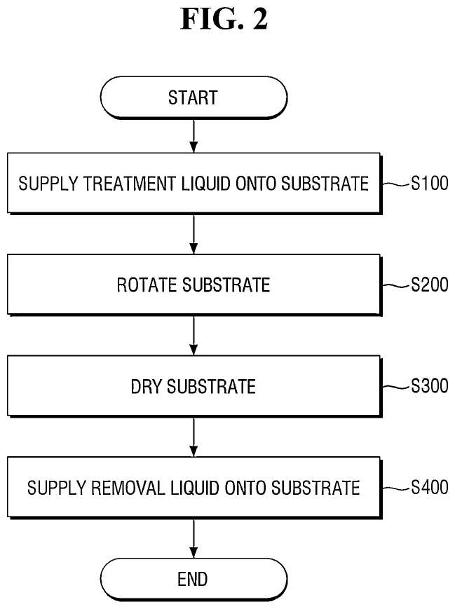

FIG. 2 is a flowchart for describing operations of a substrate treating apparatus according to some exemplary embodiments.

Referring to FIGS. 1 and 2, the treatment liquid supply apparatus 100 may supply a treatment liquid onto a substrate in the substrate treating apparatus 200 (S100). In some exemplary embodiments, the treatment liquid may be provided from the center of the substrate to an outer peripheral surface of the substrate. The treatment liquid may include, for example, a solute and a solvent having volatility.

Then, the substrate may rotate (S200). Alternatively, the rotation of the substrate (S200) may be performed simultaneously with the supply of the treatment liquid onto the substrate (S100). Alternatively, after the substrate rotates (S200), the treatment liquid may be supplied onto the substrate (S100).

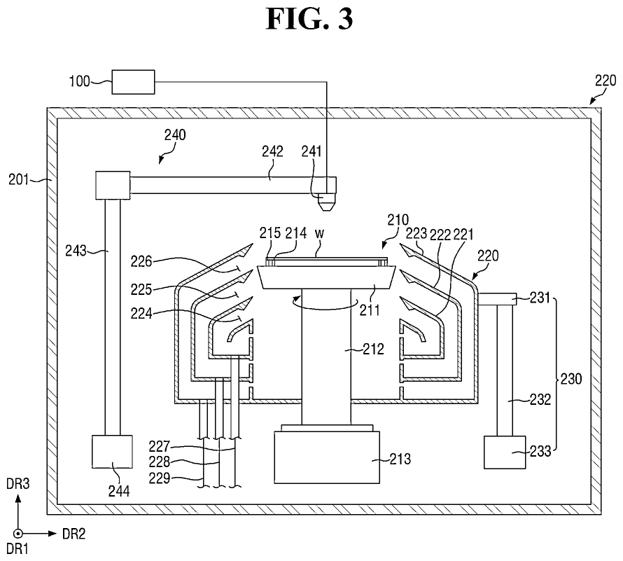

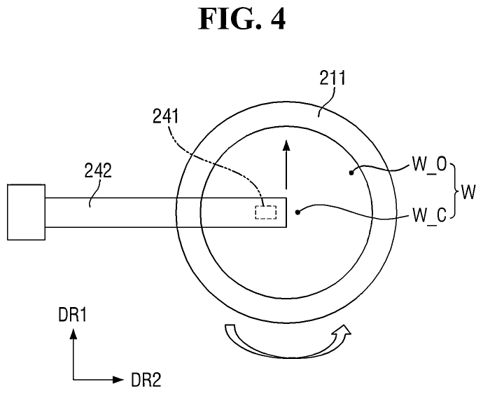

In some exemplary embodiments, the treatment liquid supplied onto the substrate may be provided from the center of the substrate toward the outer peripheral surface of the substrate. Hereinafter, a detailed description will be provided with reference to FIGS. 3 and 4.

Then, the substrate may be dried (S300). Accordingly, at least a portion of the solvent included in the treatment liquid may be volatilized, and the treatment liquid may be solidified or hardened together with particles on the substrate. The treatment liquid may become a particle holding layer.

In some exemplary embodiments, the substrate may be dried while rotating. In some other exemplary embodiments, the substrate may be dried after the rotation thereof is stopped.

In some exemplary embodiments, the substrate may be dried by at least one of heat, an inert gas, and a vacuum pressure. Hereinafter, a detailed description will be provided with reference to FIGS. 4 to 11.

Then, the removal liquid supply apparatus 300 may supply the removal liquid onto the substrate in the substrate treating apparatus 200 (S400). The particle holding layer may be removed from the substrate by the removal liquid.

FIGS. 3 and 4 are views for describing a substrate treating apparatus according to some exemplary embodiments.

Referring to FIGS. 1 and 3, the substrate treating apparatus 200 according to some exemplary embodiments may include a chamber 201, a substrate support module 210, a treatment liquid recovery module 220, an elevation module 230, and a jetting module 240. The substrate support module 210, the treatment liquid recovery module 220, the elevation module 230, and the jetting module 240 may be disposed in the chamber 201.

The substrate support module 210 may support a substrate W. The substrate support module 210 may rotate the substrate W with respect to a third direction DR3. The substrate W may rotate on a plane including a first direction DR1 and a second direction DR2. The substrate support module 210 may be disposed in the treatment liquid recovery module 220. A substrate treatment liquid used at the time of treating the substrate W may be recovered by the treatment liquid recovery module 220.

The substrate support module 210 may include a stage 211, a rotation shaft 212, a rotation driving part 213, support pins 214, and guide pins 215.

The substrate W may be seated on the stage 211. The stage 211 may be disposed on the rotation shaft 212. The stage 211 may rotate according to rotation of the rotation shaft 212. Accordingly, the substrate W disposed on the stage 211 may also rotate together with the stage 211. The stage 211 may be provided to have, for example, the same shape as that of the substrate W. However, the present exemplary embodiment is not limited thereto. The stage 211 may have various shapes.

The rotation shaft 212 may rotate by the rotation driving part 213. The rotation shaft 212 may be coupled to the rotation driving part 213 and the stage 211 to transfer a rotational force by the rotation driving part 213 to the stage 211.

The support pins 214 may fix the substrate W on the stage 211. The support pins 214 may support a lower surface of the substrate W so that the substrate W may be spaced apart from an upper surface of the stage 211 by a predetermined distance. The support pins 214 may be disposed to have an annular ring shape as a whole. The number of support pins 214 may be plural.

The guide pins 215 may be disposed on the stage 211 to support side surfaces of the substrate W. The guide pins 215 are chucking pins, and may support the substrate W so that the substrate W does not deviate from its original position when the stage 211 rotates. The number of guide pins 215 may be plural.

The treatment liquid recovery module 220 may recover the treatment liquid used to treat the substrate W. The treatment liquid recovery module 220 may be installed to surround the substrate support module 210. The treatment liquid recovery module 220 may provide a space in which a treatment process for the substrate W is performed.

When the substrate W is fixed on the substrate support module 210 and starts to rotate by the substrate support module 210, the jetting module 240 may jet the substrate treatment liquid onto the substrate W according to the control of the control apparatus 400. In this case, due to a centrifugal force generated by the rotational force of the substrate support module 210, the treatment liquid discharged onto the substrate W may be dispersed in a direction in which the treatment liquid recovery module 220 is positioned. When the treatment liquid flows into the treatment liquid recovery module 220 through an inlet (i.e., an opening 224 of a first recovery container 221, an opening 225 of a second recovery container 222, an opening 226 of the third recovery container 223, etc., to be described later), the treatment liquid recovery module 220 may recover the treatment liquid.

The treatment liquid recovery module 220 may include a plurality of recovery containers, and may recover different treatment liquids. The recovery container may be implemented as, for example, a bowl.

For example, the treatment liquid recovery module 220 may include a first recovery container 221, a second recovery container 222, and a third recovery container 223. The first recovery container 221, the second recovery container 222, and the third recovery container 223 may recover different treatment liquids. For example, the first recovery container 221 may recover water, the second recovery container 222 may recover a first chemical (e.g., any one of a material including an IPA component and a material containing an SPM component), and the third recovery container 223 may recover a second chemical (e.g., the other of the material including the IPA component and the material including the SPM component).

The first recovery container 221, the second recovery container 222, and the third recovery container 223 may be connected to recovery lines 227, 228, and 229 extending in the third direction DR3 on bottom surfaces thereof, respectively. A first treatment liquid, a second treatment liquid, and a third treatment liquid recovered through the first recovery container 221, the second recovery container 222, and the third recovery container 223, respectively, may be treated to be reusable through in a treatment liquid regeneration system (not illustrated).

The first recovery container 221, the second recovery container 222, and the third recovery container 223 may be provided in an annular ring shape in which they surround the substrate support module 210. Sizes of the first recovery container 221, the second container 222, and the third container 223 may increase as a distance from the first container 221 increases (i.e., in the second direction DR2). When an interval between the first recovery container 221 and the second recovery container 222 is defined as a first interval and an interval between the second recovery container 222 and the third recovery container 223 is defined as a second interval, the first interval may be the same as the second interval. However, the present exemplary embodiment is not limited thereto. The first interval may also be different from the second interval. That is, the first interval may be greater than the second interval or be smaller than the second interval.

The elevation module 230 may move at least one of the treatment liquid recovery module 220 and the substrate support module 210 in the third direction DR3.

Accordingly, a height of the treatment liquid recovery module 220 with respect to the substrate support module 210 (or the substrate W) may be adjusted. The elevation module 230 may include a bracket 231, a first support shaft 232, and a first driving part 233.

The bracket 231 may be fixed to an outer wall of the treatment liquid recovery module 220. The bracket 231 may be coupled to the first support shaft 232 moving in the third direction DR3 by the first driving part 233.

When the substrate W is seated on the substrate support module 210 and when the substrate W is detached from the substrate support module 210, the elevation module 230 may lower the treatment liquid recovery module 220 or elevate the substrate support module 210. Accordingly, the substrate support module 210 may be positioned above the treatment liquid recovery module 220.

When a treating process for the substrate W is performed, the elevation module 230 may elevate the treatment liquid recovery module 220 or lower the substrate support module 210, and the treatment liquid may be recovered into any one of the first recovery container 221, the second recovery container 222, and the third recovery container 223. For example, when the first treatment liquid is used as the treatment liquid, the elevation module 230 may elevate the treatment liquid recovery module 220 so that the substrate W is positioned at a height corresponding to the first opening 224 of the first recovery container 221. The present disclosure is not limited thereto, and the elevation module 230 may simultaneously move the substrate support module 210 and the treatment liquid recovery module 220.

The jetting module 240 may provide a liquid used to treat the substrate W onto the substrate W. The jetting module 240 may include a nozzle 241, a nozzle support part 242, a second support shaft 243, and a second driving part 244.

The nozzle 241 may be installed at an end of the nozzle support part 242. The nozzle 241 may discharge, for example, the treatment liquid provided from the treatment liquid supply apparatus 100 onto the substrate W. The number of nozzles 241 may be plural, and the jetting module 240 may further include a nozzle discharging the removal liquid provided from the removal liquid supply apparatus 300 onto the substrate W.

The nozzle 241 may be moved to a process position and a standby position by the second driving part 244. The process position refers to a region above the substrate W, and the standby position refers to a region other than the process position. The nozzle 241 may move to the process position when it discharges the treatment liquid onto the substrate W, and may leave the process position and move to the standby position after it discharges the treatment liquid onto the substrate W.

Referring to FIGS. 3 and 4, in some exemplary embodiments, the control apparatus 400 may control the jetting module 240. The jetting module 240 may provide the treatment liquid onto the substrate W from the center W_C of the substrate W toward an outer peripheral surface W_O of the substrate. That is, the center W_C of the substrate W may receive the treatment liquid before the outer peripheral surface W_O of the substrate W receives the treatment liquid. The outer peripheral surface W_O of the substrate W may surround the center W_C of the substrate W. The jetting module 240 may provide, for example, the treatment liquid onto the substrate W at a constant speed.

When the treatment liquid is applied onto the substrate W and the substrate W is rotated and dried, the treatment liquid applied to the outer peripheral surface W_O of the substrate W is dried before the treatment liquid applied to the center W_C of the substrate W is dried. When the treatment liquid applied to the center W_C of the substrate W is dried, the treatment liquid applied to the outer peripheral surface W_O of the substrate W may be excessively dried. Accordingly, the treatment liquid applied to the outer peripheral surface W_O of the substrate W is strongly bonded to a wafer and thus, is not removed by the removal liquid and is highly likely to remain on the substrate W.

However, in the substrate treating apparatus according to some exemplary embodiments, the jetting module 240 provides the treatment liquid from the center W_C of the substrate W toward the outer peripheral surface W_O, and thus, the treatment liquid provided to the center W_C of the substrate W has a longer drying time than the treatment liquid provided on the outer peripheral surface W_O. Accordingly, the treatment liquid provided onto the substrate W may be more uniformly dried. Accordingly, the treatment liquid is more easily removed, and thus, a yield of the substrate W may be improved or increased.

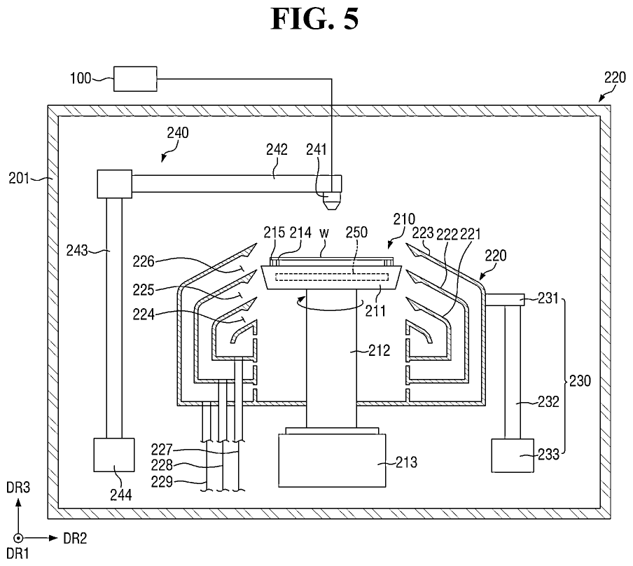

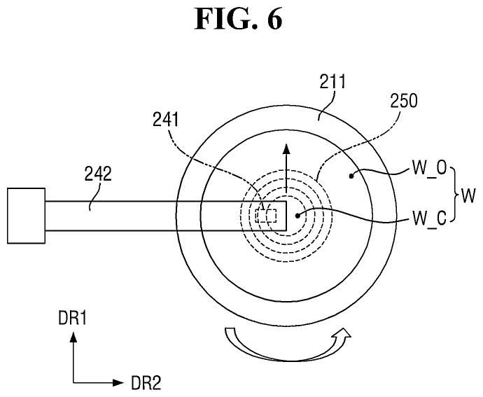

FIGS. 5 and 6 are views for describing a substrate treating apparatus according to some exemplary embodiments. For convenience of explanation, contents different from those described with reference to FIGS. 1 to 4 will be mainly described.

Referring to FIGS. 5 and 6, the substrate treating apparatus 200 according to some exemplary embodiments may further include a heating member 250. The heating member 250 may be disposed in the stage 211.

The heating member 250 may overlap the center W_C of the substrate W, but may not overlap the outer peripheral surface W_O of the substrate W. The heating member 250 may have a ring shape. The heating member 250 may have a shape of a plurality of rings having different radii with respect to the center W_C of the substrate W. For example, the heating member 250 may be a heating wire formed in the stage 211.

The control apparatus 400 may control the heating member 250. The heating member 250 may provide heat to the substrate W after the treatment liquid is supplied to the substrate W. The heating member 250 may provide the heat to the substrate W that rotates. The heating member 250 may provide the heat to the center W_C of the substrate W, but may not provide the heat to the outer peripheral surface W_O of the substrate W. That is, the heating member 250 may promote drying of the treatment liquid provided to the center W_C of the substrate W. Accordingly, the treatment liquid provided onto the substrate W may be more uniformly dried. The heat may be heat at such a level that damage to the substrate W does not occur.

For example, the control apparatus 400 may control an operation of the heating member 250 by monitoring whether or not the treatment liquid provided onto the substrate W is uniformly applied. For example, the control apparatus 400 may control whether or not the heating member 250 operates, the heat provided by the heating member 250, a time when the heating member 250 provides the heat, and the like, according to a monitoring result.

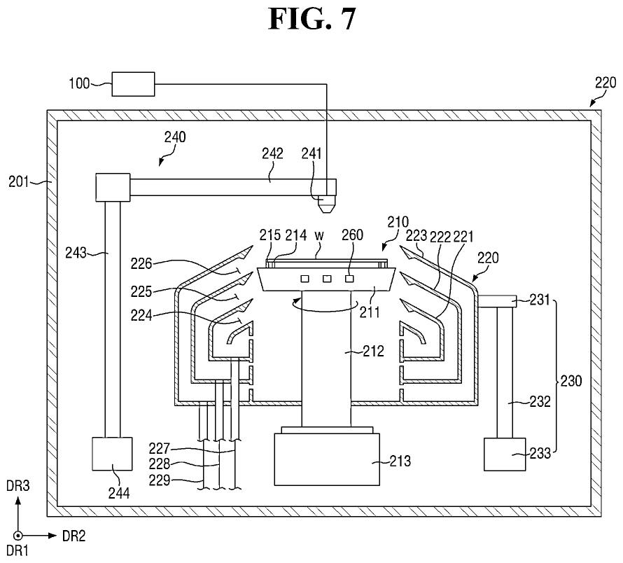

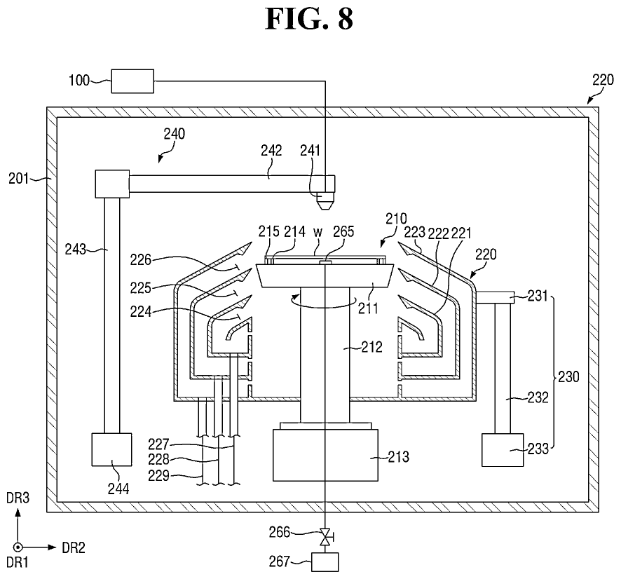

FIGS. 7 and 8 are views for describing a substrate treating apparatus according to some exemplary embodiments. For convenience of explanation, contents different from those described with reference to FIG. 6 will be mainly described.

Referring to FIG. 7, heating members 260 included in the substrate treating apparatus 200 according to some exemplary embodiments may be heaters. The number of heating members 260 may be plural, and the plurality of heating members 260 may be spaced apart from each other in the stage 211. The heating members 260 may overlap the center W_C of the substrate W, but may not overlap the outer peripheral surface W_O of the substrate W. Accordingly, heat may be applied to the center W_C of the substrate W.

Referring to FIG. 8, the substrate treating apparatus 200 according to some exemplary embodiments may further include a back nozzle 265 disposed on the stage 211. The back nozzle 265 may be disposed at the center of the stage 211. The back nozzle 265 may be connected to a storage part 267 in which a heated fluid is stored. A valve 266 may be disposed between the back nozzle 265 and the storage part 267, and the control apparatus 400 (see FIG. 1) may control on/off of the valve 266.

The back nozzle 265 may jet the heated fluid to a back surface of the substrate W. The back nozzle 265 may jet the heated fluid to the center W_C of the substrate W. Accordingly, heat may be applied to the center W_C of the substrate W.

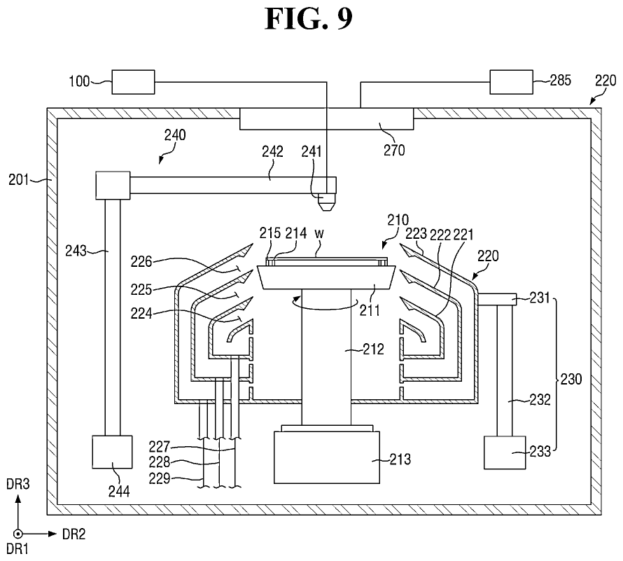

FIGS. 9 to 11 are views for describing a substrate treating apparatus according to some exemplary embodiments. For convenience of explanation, contents different from those described with reference to FIGS. 1 to 4 will be mainly described.

Referring to FIG. 9, the substrate treating apparatus 200 according to some exemplary embodiments may further include a fan filter unit 270. The fan filter unit 270 may be disposed at an upper portion of the chamber 201.

The control apparatus 400 may control the fan filter unit 270. The fan filter unit 270 may supply external air into the chamber 201. The fan filter unit 270 may be connected to an inert gas supply unit 285. The fan filter unit 270 may provide an inert gas from the inert gas supply unit 285 to the substrate W after the treatment liquid is supplied to the substrate W. The fan filter unit 270 may provide the inert gas to the substrate W that rotates. The fan filter unit 270 may provide the inert gas toward the center W_C of the substrate W, for example. Accordingly, drying of the treatment liquid applied to the center W_C of the substrate W may be promoted. The inert gas may include, for example, nitrogen.

For example, the control apparatus 400 may control an operation of the fan filter unit 270 by monitoring whether or not the treatment liquid provided onto the substrate W is uniformly applied. For example, the control apparatus 400 may control whether or not the fan filter unit 270 operates, an operation time of the fan filter unit 270, and the like, according to a monitoring result.

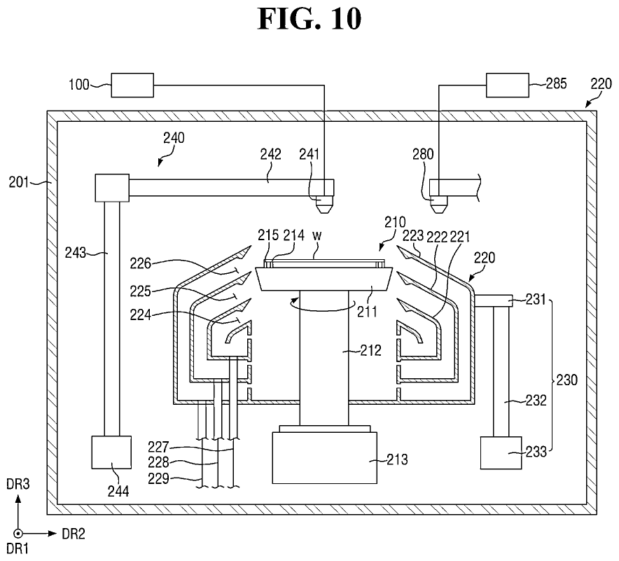

Referring to FIG. 10, the substrate treating apparatus 200 according to some exemplary embodiments may further include a nozzle 280. The nozzle 280 may be connected to the inert gas supply unit 285.

The control apparatus 400 may control the nozzle 280. The nozzle 280 may provide an inert gas from the inert gas supply unit 285 onto the substrate W after the treatment liquid is supplied to the substrate W. The nozzle 280 may provide the inert gas to the substrate W that rotates. The nozzle 280 may be disposed on the center W_C of the substrate W and may provide the inert gas toward the center W_C of the substrate W. Accordingly, drying of the treatment liquid applied to the center W_C of the substrate W may be promoted.

For example, the control apparatus 400 may control an operation of the nozzle 280 by monitoring whether or not the treatment liquid provided onto the substrate W is uniformly applied. For example, the control apparatus 400 may control whether or not the nozzle 280 operates, an operation time of the nozzle 280, an operation position of the nozzle 280, and the like, according to a monitoring result.

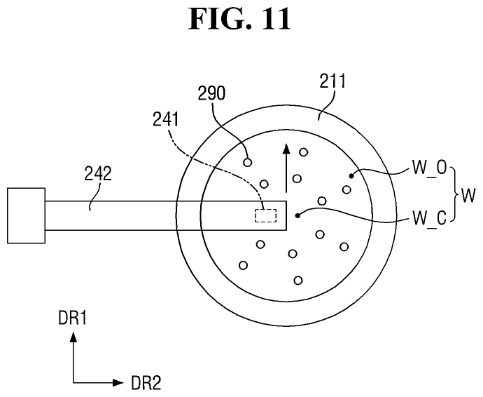

Referring to FIGS. 3 and 11, in the substrate treating apparatus according to some exemplary embodiments, the stage 211 may include vacuum holes 290. The vacuum holes 290 may be formed in the upper surface of the stage 211. The vacuum holes 290 may be disposed between the support pins 214.

The vacuum hole 290 may be connected to a pressure reducing member providing a vacuum pressure. The control apparatus 400 may control the vacuum holes 290 or the pressure reducing member. The vacuum holes 290 may provide a vacuum pressure to the substrate W after the treatment liquid is supplied to the substrate W. The vacuum holes 290 may provide the vacuum pressure to the substrate W after the rotation of the substrate W is stopped.

The number of vacuum holes 290 may be plural. For example, the vacuum holes 290 may be formed over the entire upper surface of the stage 211. Accordingly, the vacuum pressure may be provided over the entire substrate W.

The exemplary embodiments of the present disclosure have been described hereinabove with reference to the accompanying drawings, but it will be understood by one of ordinary skill in the art to which the present disclosure pertains that various modifications and alterations may be made without departing from the technical spirit or essential feature of the present disclosure. Therefore, it is to be understood that the exemplary embodiments described above are illustrative rather than being restrictive in all aspects.

What is claimed is:

1. A substrate treating apparatus comprising:
a stage on which a substrate is seated, in a chamber; and
a treatment liquid supply apparatus supplying a treatment liquid containing a solvent and a solute onto the substrate,
wherein the treatment liquid supply apparatus supplies the treatment liquid onto the substrate while moving from a center of the substrate to an outer peripheral surface of the substrate.

2. The substrate treating apparatus of claim 1, wherein the treatment liquid supply apparatus supplies the treatment liquid to the substrate at a constant speed.

3. The substrate treating apparatus of claim 1, further comprising a heating member applying heat to the substrate after the treatment liquid supply apparatus supplies the treatment liquid to the substrate.

4. The substrate treating apparatus of claim 3, wherein the heating member applies heat to the center of the substrate, but does not apply heat to the outer peripheral surface of the substrate.

5. The substrate treating apparatus of claim 3, wherein the heating member is a heater disposed in the stage.

6. The substrate treating apparatus of claim 3, wherein the heating member is a heating wire disposed in the stage.

7. The substrate treating apparatus of claim 1, further comprising a back nozzle disposed on the substrate and jetting a heated fluid to the center of the substrate after the treatment liquid supply apparatus supplies the treatment liquid to the substrate.

8. The substrate treating apparatus of claim 1, further comprising a gas supply member supplying an inert gas to the center of the substrate after the treatment liquid supply apparatus supplies the treatment liquid to the substrate.

9. The substrate treating apparatus of claim 1, further comprising a fan filter unit supplying external air into the chamber,
wherein after the treatment liquid supply apparatus supplies the treatment liquid to the substrate, the fan filter unit supplies an inert gas to the center of the substrate.

10. The substrate treating apparatus of claim 1, further comprising vacuum holes providing a negative pressure to the substrate after the treatment liquid supply apparatus supplies the treatment liquid to the substrate.

11. The substrate treating apparatus of claim 10, further comprising a rotation driving part rotating the stage,
wherein the rotation driving part does not rotate the stage while the vacuum holes provide the negative pressure to the substrate.

12. A substrate treating apparatus comprising:
a stage on which a substrate is seated, in a chamber;
a treatment liquid supply apparatus supplying a treatment liquid containing a solvent and a solute onto the substrate;
a removal liquid supply apparatus supplying a removal liquid onto the substrate; and
a control apparatus controlling the treatment liquid supply apparatus and the removal liquid supply apparatus,
wherein the solvent has volatility,
at least a portion of the solvent is volatilized from the treatment liquid supplied onto the substrate, such that the treatment liquid is solidified or hardened to become a particle holding layer,
after the particle holding layer is formed on the substrate, the removal liquid is supplied from the removal liquid supply apparatus to the particle holding layer, such that the particle holding layer is removed from the substrate, and
the treatment liquid supply apparatus supplies the treatment liquid onto the substrate while moving from a center of the substrate to an outer peripheral surface of the substrate.

13. The substrate treating apparatus of claim 12, further comprising at least one of a heating member applying heat to the substrate, a gas supply member supplying an inert gas to the substrate, and vacuum holes providing a negative pressure to the substrate,
wherein the control apparatus activates the heating member, the gas supply member, and the vacuum holes after the treatment liquid supply apparatus provides the treatment liquid to the substrate.

14. A substrate treating method comprising:
providing a substrate treatment liquid onto a substrate;
drying the substrate,
wherein the substrate treatment liquid is provided from a center of the substrate to an outer peripheral surface of the substrate.

15. The substrate treating method of claim 14, wherein the substrate treatment liquid is provided at a constant speed.

16. The substrate treating method of claim 14, wherein the drying of the substrate includes rotating the substrate.

17. The substrate treating method of claim 14, wherein the drying of the substrate includes applying heat to the center of the substrate.

18. The substrate treating method of claim 14, wherein the drying of the substrate includes supplying an inert gas to the center of the substrate.

19. The substrate treating method of claim 14, wherein the drying of the substrate includes providing a negative pressure to the substrate.

20. The substrate treating method of claim 19, wherein the providing of the negative pressure to the substrate includes stopping of rotation of the substrate.
